(19) United States
(12) Patent Application Publication
(10) Pub. No.: US 2003/0101402 A1
(43) Pub. Date: May 29, 2003

(54) Hard-output iterative decoder

(75) Inventors: Ofer Amrani, Tel Aviv (IL); Meir Ariel, Tel Aviv (IL)

Correspondence Address: G.E. EHRLICH (1995) LTD., c/o ANTHONY CASTORINA, SUITE 207, 2001 JEFFERSON DAVIS HIGHWAY, ARLINGTON, VA, 22202, US

(73) Assignee: Cute Ltd.

(21) Appl. No.: 09/983,564

(22) Filed: Oct. 25, 2001

(51) Int. Cl. H03M 13/00; H03M 13/03

(52) U.S. Cl. 714/755; 714/786

(57) ABSTRACT

A decoder, for decoding a data sequence received from a noisy channel into an estimate of an input sequence, comprises a soft-decision decoder combined with a soft-input calculator. The decoder and calculator are interconnected, and jointly converge on an output which is an estimate of a transmitted sequence.

### FIELD OF THE INVENTION

The present invention relates to iterative decoding of turbo codes.

### BACKGROUND OF THE INVENTION

Turbo codes are employed in modem digital communication systems to protect high bit-rate transmitted information from error. Turbo codes are generally constructed as a concatenation of two recursive systematic convolutional codes, linked together by some non-uniform interleaving. The term turbo code originally described the parallel concatenation of two recursive systematic convolutional codes (PCCC). Other possibilities are serial concatenation (SCCC) and using block codes as component codes. PCCC is now becoming a standard error correction scheme in several wireless air interfaces. For example, the 3GPP (Third Generation Partnership Project for wireless systems) standard employs a PCCC with M=8 states and a block length of up to N=5 120 information bits. In a cdma2000 system, N can be as high as 20000.

Although convolutional in nature, turbo codes cannot be processed directly using a Viterbi decoder. The Viterbi decoding algorithm models a code as a trellis, with branches depicting legal transitions from state to state. Each state represents a combination of input digits used by the encoder to select the transmitted symbol, and each branch is associated with a branch metric. As each symbol in the received sequence is decoded, the Euclidean distance between the received symbol and each possible path through the trellis is measured. A single surviving path is selected for each state.

A trellis diagram corresponding to a turbo code typically has a huge number of states, making implementation of the Viterbi algorithm impractical. Therefore, an iterative approach is employed with two elementary decoders, each associated with one of the two constituent codes. The two decoders are usually serially concatenated, where the first decoder yields weighted, or soft-output decisions that are fed to the second decoder as a priori information. The soft-outputs of the second decoder are then fed back to the first decoder for the second iteration, and so on. Only the so-called extrinsic information, i.e. new information that is generated by a decoder, is passed between the decoders.

The optimal soft-output decoder is the so-called MAP (maximum a posteriori) decoder, which uses both backward and forward decoding to efficiently determine the soft-output. The MAP decoder is optimal in the sense that it minimizes the decoded bit error probability for each information bit based on all received bits. Because of memory, processing, and numerical tradeoffs, MAP decoding is usually limited to a sub-optimal approximation. Convolutional codes composing a turbo code are graphically represented as a trellis. MAP-type decoders (log-MAP, MAP, max-log-MAP, constant-log-MAP, etc.) utilize forward and backward generalized Viterbi recursions on the trellis in order to provide soft outputs, as is known in the art.

Because of the Markov nature of the encoded sequence (wherein previous states cannot affect future states or future output branches), the MAP bit probability can be broken into the past (beginning of trellis to the present state), the present state (branch metric for the current value), and the future (end of trellis to current value).More specifically, the MAP decoder performs forward and backward recursions up to a present state, wherein the past and future probabilities are used along with the present branch metric to generate an output decision. The principles of providing soft output decisions are well known in the art, and several variations of the above-described decoding methods exist.

Most of the soft-input soft-output (SISO) decoders considered for turbo codes are based on the MAP algorithm in a paper by L. R. Bahl, J. Cocke, F. Jelinek, and J. Raviv entitled “Optimal Decoding of Linear Codes for Minimizing Symbol Error Rate”, IEEE Transactions on Information Theory, Vol. IT-20, March 1974, pp. 284-7 (the “BCJR algorithm” or “BCJR method”), contents of which are hereby incorporated by reference. MAP algorithms not only minimize the probability of error for an information bit given the received sequence, they also provide the probability that the information bit is either a 1 or 0 given the received sequence. The BCJR algorithm provides a soft output decision for each bit position (trellis section) wherein the influences of the soft inputs within the block are broken into contributions from the past (earlier soft inputs), the present soft input, and the future (later soft inputs). The BCJR decoding algorithm requires a forward and a backward generalized Viterbi recursion on the trellis to arrive at an optimal soft output for each trellis section, or stage. These a posteriori probabilities, or more commonly the log-likelihood ratio (LLR) of the probabilities, are passed between SISO decoding steps in iterative turbo decoding. The LLR for information bit uₜ is:

$${Λ}_{t} = log \frac{{\sum }_{( m , n ) ∈ {β}^{1}} {α}_{t - 1} ( n ) {γ}_{t} ( n , m ) {β}_{t} ( m )}{{\sum }_{( m , n ) ∈ {β}^{0}} {α}_{t - 1} ( n ) {γ}_{t} ( n , m ) {β}_{t} ( m )} , \qquad ( 1 )$$

for all bits in the decoded sequence (t=1 to N). In equation (1), the probability that the decoded bit is equal to 1 (or 0) in the trellis given the received sequence is composed of a product of terms due to the Markov property of the code. The Markov property may be stated as the assumption that the past and the future are independent given the present. The present, γₜ(n,m), may be regarded as the probability of being in state m at time t and generating the symbol yₜ when the previous state at time t−1 was n. The present operates as a branch metric. The past, αₜ(m), may be regarded as the probability of being in state m at time t with the received sequence {y₁, . . . , yₜ}, and the future, βₜ(m), may be regarded as probability of generating the received sequence {yₜ₊₁, . . . y_{N}} from state m at time t. The probability αₜ(m) can be expressed as function of αₜ₋₁(m) and γₜ(n,m) and is called the forward recursion.

$${α}_{i} ( m ) = {\sum }_{n = 0}^{M - 1} {α}_{i - 1} ( n ) {γ}_{i} ( n , m ) , m = 0 , … , M - 1 ,$$

where M is the number of states. The reverse or backward recursion for computing the probability βₜ(n) from βₜ₊₁(n) and γₜ(n,m) is:

$${β}_{i} ( n ) = {\sum }_{m = 0}^{M - 1} {β}_{i + 1} ( m ) {γ}_{i} ( n , m ) , n = 0 , … , M - 1.$$

The overall a posteriori probabilities in equation (1) are computed by summing over the branches in the trellis B¹ (B⁰) that correspond to uₜ=1 (or 0).

The LLR in equation (1) requires both the forward and backward recursions to be available at time t. The BCJR method for meeting this requirement is to compute and store the entire backward recursion, and recursively compute αₜ(m) and Λₜ from t=1 to t=N using αₜ₋₁ and βₜ.

In terms of computational complexity, the BCJR method requires N*M state updates for the backward recursion (M state updates per trellis section, N trellis sections in the code) and provides optimal performance. In practice, a backward recursion is first performed by a processor across the entire block and stored in memory. The processor then performs a forward recursion. The results of the backward and forward recursions are used with the present state and stored future state to arrive at a soft output decision for each stage. In this case the processor operates on each state twice, once to generate and store the backward recursion states, and once to generate the forward recursion state.

To address the computational complexity and memory utilization problems of the soft-output decoder, a sliding window method was developed. The sliding window technique is described in a paper by S. Benedetto, D. Divsalar, G. Montorsi, and F. Pollara, entitled “Algorithm for continuous decoding of turbo codes,” Electronics Letters, Vol. 32, Feb. 15, 1996, pp. 314-315.

Another prior art decoder, described in U.S. Pat. No. 5,933,462 to Viterbi et al. (and similarly in a paper of S. Pietrobon and S. Barbulescu, “A Simplification of the Modified Bahl et al. Decoding Algorithm for Systematic Convolutional Codes,” Int. Symp. On Inform. Theory and its Applications, Sydney, Australia, pp.1073-7, November 1994, revised Jan. 4, 1996 and S. Pietrobon, “Efficient Implementation of Continuous MAP Decoders and a Synchronisation Technique for Turbo Decoders,” Int. Symp. On Inform. Theory and its Applications, Victoria, B.C., Canada, pp. 586-9, September 1996) comprises another sliding window technique. Contents of the above articles are hereby incorporated by reference.

The use of even the sub-optimal Max-Log-MAP algorithm for constituent code decoding makes heavy demands on processing resources. One prior art implementation of this algorithm, the Max-Log-MAP algorithm on the Motorola DSP56603 80 MIPS DSP, enables performance of 48.6 kbit/s. Given such a performance level, forty processors must work in parallel in order to provide the target real-time performance of 2 Mbit/s as defined in the 3G standards.

Another prior art device is the state-of-the-art Motorola StarCore SC140 DSP,which cannot support a processing rate of more than 1 Mbit/s. A hand written assembly code required 36 cycles per code/iteration/bit, resulting in 288 cycles per 4 iterations, or equivalently˜1 Mbit/s on a 300M cycles per second DSP.

### SUMMARY OF THE INVENTION

It is a purpose of the present embodiments to provide a turbo code decoder that is significantly less complex than an optimal decoder, yet provides close to optimal results for a relatively small increase in the required signal to interference noise ratio (SINR) at the decoder input.

It is a purpose of the present embodiments to provide a turbo code decoder that can be used during early deployment of cellular wireless networks, to provide the required quality of service (QoS) for lower cost, and with lower handset power consumption.

It is a purpose of the present embodiments to provide a turbo code decoder that can be deployed in cellular wireless networks, to trade data rate with SINR when the conditions allow an increase in the SINR.

According to a first aspect of the present invention there is thus provided a decoder, for decoding a data sequence received from a noisy channel into an estimate of an input sequence. The decoder comprises a soft-decision decoder combined with a soft-input calculator. The elements of the decoder are interconnected, thereby to jointly converge on the estimate.

In a preferred embodiment, the data sequence is a turbo code comprising at least two interleaved sub-sequences, the soft-decision decoder comprising at least two soft-decision sub-decoders, and the soft-input calculator comprising at least two soft-input sub-calculators. Each soft-decision sub-decoder is combined with the respective soft-input sub-calculator, for decoding the respective sub-sequences.

A further preferred embodiment additionally comprises a separator operable to separate the turbo code into the sub-sequences.

A further preferred embodiment additionally comprises a metric calculator operable to calculate sets of a-priori metrics for each of the sub-sequences.

In a further preferred embodiment, the a-priori metrics for at least one of the sub-sequences are Likelihood metrics.

A further preferred embodiment additionally comprises an initializer operable to initialize a set of soft-input metrics for at least one of the sub-sequences.

A further preferred embodiment additionally comprises an analyzer operable to analyze a current decoding state of the decoder, to determine whether a predetermined condition is met. If the predetermined condition is met the decoding process is terminated, and a hard-output decoded estimate of the input sequence is output.

In a further preferred embodiment, the soft-decision sub-decoder comprises a trellis decoder.

A further preferred embodiment additionally comprises an iteration counter operable to count a number of decoding iterations performed by the decoder.

According to a second aspect of the present invention there is thus provided an iterative turbo code decoder for decoding a turbo-encoded data sequence received from a noisy channel, comprising a separator, a metric calculator, an initializer, a first soft-decision decoder, a first soft-input calculator, a second soft-decision decoder, a second soft-input calculator, and an analyzer. The separator is operable to separate the received data sequence into a first, a second, and a third component data sequence. The metric calculator has an input from the separator, and is operable to calculate a set of a-priori metrics for each of the component data sequences. The initializer has an input from the metric calculator, and is operable to initialize a first soft-input metric sequence. The first soft-decision decoder has inputs from the metric calculator and the initializer, and is operable to produce a first soft-decision decoded sequence. The first soft-input calculator has inputs from the metric calculator, the first soft-decision decoder, and the initializer, and is operable to calculate and subsequently update the values of a second soft-input metric sequence. The second soft-decision decoder has inputs from the metric calculator and the first soft-input calculator, and is operable to produce a second soft-decision decoded sequence. The second soft-input calculator has inputs from the metric calculator, the first soft-input calculator, and the second soft-decision decoder, and outputs to the first soft-decision decoder and the first soft-input calculator. The second soft-input calculator is operable to calculate and subsequently update the values of the first soft-input metric sequence. The analyzer has inputs from the first and the second soft-decision decoders, and is operable to analyze a current decoding state of the decoder, to terminate the decoding process if a predetermined condition is met, and to output a hard-output decoded estimate of the first sequence.

In a preferred embodiment, at least one of the soft-decision decoders comprises a trellis decoder.

In a further preferred embodiment, the first and the second soft-input calculators are connected in a loop, such that an output of the first soft-input calculator is connected to an input of the second soft-input calculator, and an output of the second soft-input calculator is connected to an input of the first soft-input calculator.

In a further preferred embodiment, at least one of the soft-input calculators comprises an interleaver for interleaving data sequences.

In a further preferred embodiment, the separator comprises a puncturer.

In a further preferred embodiment, the analyzer is operable to terminate the decoding process when a predetermined reliability condition is fulfilled.

In a further preferred embodiment, the analyzer is operable to terminate the decoding process when a decoded sequence produced by the turbo code decoder is a codeword of a predetermined encoding scheme.

In a further preferred embodiment, the analyzer comprises a Euclidean distance measurer operable to terminate the decoding process when a Euclidean distance between a component data sequence and a decoded sequence produced by the turbo code decoder falls within a predetermined range.

In a further preferred embodiment, the analyzer is operable to terminate the decoding process when two decoded sequences estimating the first component data sequence fulfill a convergence condition.

In a further preferred embodiment, the analyzer comprises a Hamming distance measurer operable to terminate the decoding process when the first soft-decision decoded sequence and the second soft-decision decoded sequence differ from each other in no more than a predetermined number of positions.

In a further preferred embodiment, the analyzer comprises a Hamming distance measurer operable to terminate the decoding process when soft-decision decoded sequences obtained after at least two successive decoding iterations differ in no more than a predetermined number of positions.

In a further preferred embodiment, the analyzer is operable to terminate the decoding process when the decoding process has reached a predetermined level of complexity.

In a further preferred embodiment, the analyzer comprises a counter operable to terminate the decoding process after a predetermined number of decoding iterations.

In a further preferred embodiment, the a-priori metrics for at least one of the component data sequences are Likelihood metrics.

In a further preferred embodiment, wherein the initializer is operable to initialize a set of soft-input metrics by setting the set of soft-input metrics equal to the a-priori metrics of the first data sequence.

A preferred embodiment additionally comprises an iteration counter operable to maintain an iteration count of a number of decoding iterations performed by the decoder.

In a further preferred embodiment, the first soft-input calculator is operable to calculate the values of the second soft-input metric sequence additionally based on the iteration count.

In a further preferred embodiment, the second soft-input calculator is operable to calculate the values of the first soft-input metric sequence additionally based on the iteration count.

According to a third aspect of the present invention there is thus provided an iterative method for decoding a data sequence encoded using turbo coding from a data sequence received from a noisy channel by: separating the received data sequence into a first, a second, and a third component data sequence, calculating a set of a-priori metrics for each of the component data sequences, initializing at least one of a first set and a second set of soft-input metrics, and performing an estimation cycle to decode the first component sequence. The estimation cycle is performed by: producing a first soft-decision decoded sequence from the first set of soft-input metrics and from the set of a-priori metrics for the second sequence, calculating the values of the second set of soft-input metrics from the first soft-decision sequence, from the set of a-priori metrics for the first sequence, and from the first set of soft-input metrics, producing a second soft-decision decoded sequence from the second set of soft-input metrics and from the set of a-priori metrics for the third sequence, and determining if a predetermined condition for terminating the decoding process is met. If the predetermined condition is met, the decoding process is discontinued by outputting a hard-output decoded sequence estimating the first sequence. If the predetermined condition is not met, the decoding process is continued by: updating the first set of soft-input metrics from the second soft-decision decoded sequence, from the set of a-priori metrics for the first sequence, and from the second set of soft-input metrics, and repeating the estimation cycle to update the first and second soft-decision decoded sequences and the first and second soft-input metrics until the predetermined condition is met.

In a preferred embodiment, the method comprises interleaving within the decoding loop to ensure alignment of the decoded sequences within the loop.

In a further preferred embodiment, initializing a set of soft-input metrics comprises setting the set of soft-input metrics equal to the a-priori metrics of the first data sequence.

In a further preferred embodiment, producing a soft-decision decoded sequence is performed by trellis decoding.

In a further preferred embodiment, separating the received data sequence into component data sequences is performed by puncturing the received sequence.

In a preferred embodiment, determining if a predetermined condition for terminating the decoding process is met comprises determining whether at least one of the decoded sequences fulfills a predetermined reliability condition.

In a further preferred embodiment, the predetermined reliability condition includes a decoded sequence comprising at least one codeword of a predetermined encoding scheme.

In a further preferred embodiment, the predetermined reliability condition includes a Euclidean distance between a component data sequence and a decoded sequence falling within a predetermined range.

In a preferred embodiment, determining if a predetermined condition for terminating the decoding process is met comprises determining whether two decoded sequences fulfill a convergence condition.

In a further preferred embodiment, the convergence condition comprises the first soft-decision decoded sequence and the second soft-decision decoded sequence differing in no more than a predetermined number of positions.

In a further preferred embodiment, the convergence condition includes a soft-decision decoded sequence yielded by at least two estimation cycles differing in no more than a predetermined number of positions.

In a preferred embodiment, the predetermined condition for terminating the decoding process is a predetermined level of complexity of the decoding process.

In a further preferred embodiment, the predetermined level of complexity of the decoding process comprises having reached a predetermined number of decoding iterations.

In a further preferred embodiment, the a-priori metrics for at least one of the component data sequences are Likelihood metrics.

In a preferred embodiment, the method further comprises the step of maintaining an iteration count of the number of estimation cycles performed during the decoding process.

In a preferred embodiment, the values of the first set of soft-input metrics are further calculated from the iteration count.

In a further preferred embodiment, the values of the second set of soft-input metrics are further calculated from the iteration count.

### BRIEF DESCRIPTION OF THE DRAWINGS

For a better understanding of the invention and to show how the same may be carried into effect, reference will now be made, purely by way of example, to the accompanying drawings, in which:

FIG. 1 is a simplified block diagram of a turbo code encoder.

FIG. 2 is a simplified block diagram of a turbo code decoder according to a preferred embodiment of the present invention.

FIGS. 3a and 3b are simplified flowcharts of methods for decoding turbo codes according to preferred embodiments of the present invention.

### DESCRIPTION OF THE PREFERRED EMBODIMENTS

Currently known iterative decoding algorithms are significantly less complex than optimal decoding, yet remain computationally complex due to the use of costly decoders for the component codes. There is a need for a decoder that reduces overall processing requirements for decoding turbo codes. The turbo code decoder embodiments described below provide a solution that enables a dramatic decrease in computational complexity with only a small corresponding increase in required signal to interference noise ratio (SINR) at the decoder input.

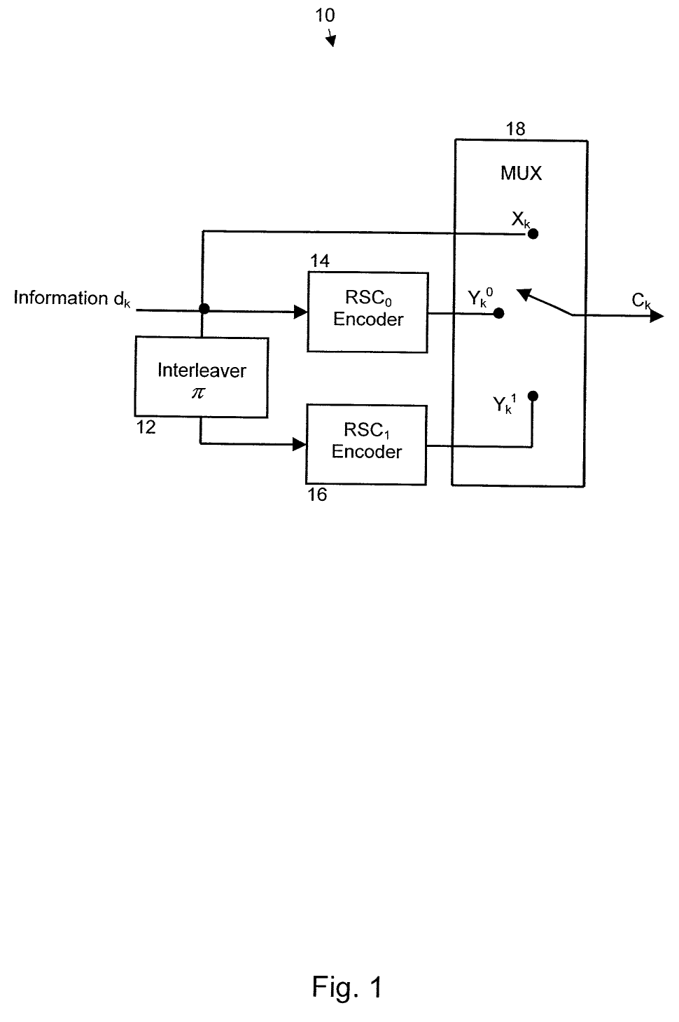

Reference is now made to FIG. 1, which shows a simplified block diagram of a turbo code encoder 10. The encoder 10 comprises an interleaver 12, two recursive systematic convolutional (RSC) encoders 14 and 16, and a multiplexer 18. The input to the turbo code encoder 10 is an input data sequence d. The first encoder RSC₀ 14 encodes the input data sequence d directly, forming data sequence Y⁰. Interleaver 12 interleaves the input data sequence d. This interleaved sequence is the input to the second encoder RSC₁ 16. RSC, encoder 16 encodes the interleaved version of data sequence d, forming data sequence Y¹. The multiplexer 18 combines the three data sequences into output sequence C. The coded sequence is given by {Cₖ}, with

$${C}_{k} = ( {X}_{k} , {Y}_{k}^{0} , {Y}_{k}^{1} ) ,$$

where Xₖ=dₖ is the information bit at time k,

$${Y}_{k}^{0}$$

is the parity output bit from the encoder RSC₀ 14, and

$${Y}_{k}^{1}$$

is the parity output bit from the encoder RSC₁ 16. This output sequence is then transmitted over a noisy channel. For notational simplicity, when reference is made to an entire sequence, the k subscript, used to indicate a specific bit in the sequence, will be omitted.

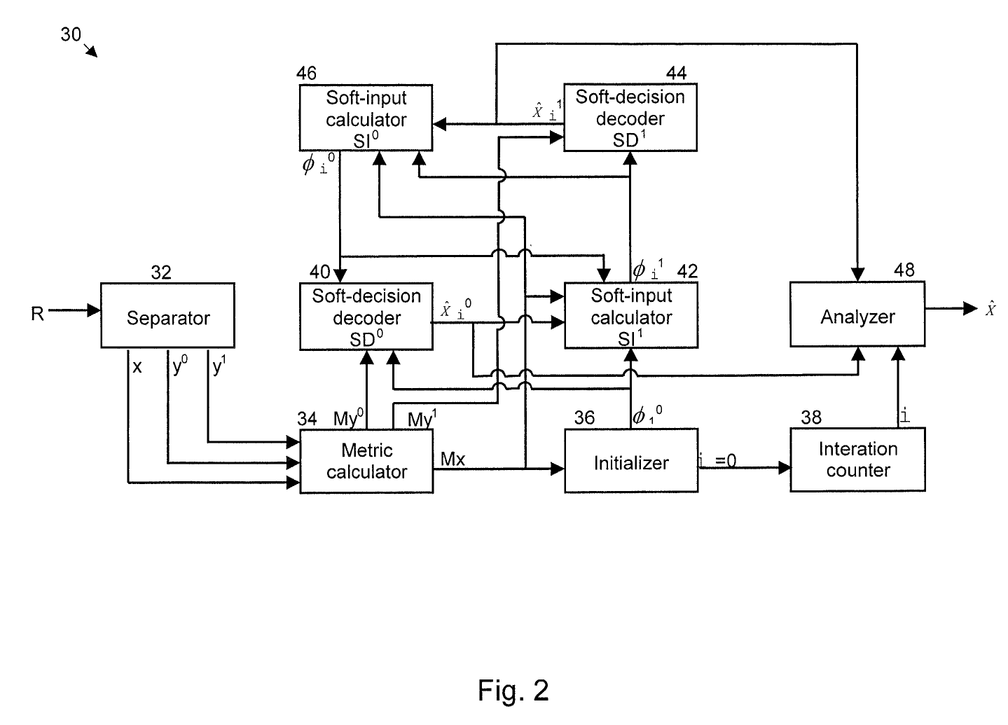

Reference is now made to FIG. 2, which is a simplified block diagram of a turbo code decoder 30. The decoder 30 comprises a Separator 32, Metric Calculator 34, and Initializer 36, which perform a series of initialization operations required to begin the decoding process. Soft-decision Decoder SD0 40, Soft-input Calculator SI1 42, Soft-decision Decoder SD1 44, and Soft-input Calculator SI0 46 are connected together to perform an iterative decoding loop to determine the original input data sequence from the received sequence R. Iteration Counter 38 maintains an iteration count, denoted i below, and increments it as necessary. Analyzer 48 monitors the decoding process, determines when the decoding process is completed, and outputs the hard-output decoded sequence \hat{X}, as will be explained in detail below.

The received sequence is denoted by R, where

$${R}_{k} = ( {x}_{k} , {y}_{k}^{0} , {y}_{k}^{1} )$$

is a noisy, and possibly distorted, version of the transmitted symbol

$${C}_{k} = ( {X}_{k} , {Y}_{k}^{0} , {Y}_{k}^{1} ) .$$

In a preferred embodiment, the information sequence X that is input to the turbo encoder contains several coded bits, so that the sequence is a codeword of a Cyclic Redundancy Check (CRC) code, thus enabling more reliable detection on the receiver side.

Initialization is as follows:

a) Separator 32 separates the received sequence R into the component subsequences, x, y⁰, and y¹. In a preferred embodiment, this separation is performed by a puncturer.

b) Metric calculator 34 calculates an a priori metric sequence for each of the sub-sequences, yielding sequences M_{X}, M_{Y}⁰, and M_{Y}¹. In the preferred embodiment, the a priori metric sequences are Likelihood metrics. These a priori metric sequences are stored for further use by the decoder 30.

c) Initializer 36 initializes the iteration loop count, i, and the soft-input metric sequence,

$${φ}_{i}^{0} ,$$

as follows:

i=1

$${φ}_{1}^{0} , = {M}_{x} .$$

The iteration loop count i tracks the number of times the iterative decoding loop is performed. The soft-input metric sequence

$${φ}_{1}^{0}$$

is used by the first Soft-decision Decoder SD0 40 to begin the decoding process.

The iterative decoding process begins after the initialization is completed. The iterative process is based on two Soft-decision Decoders SD0 40 and SD1 44. In the preferred embodiment, each of these decoders is a conventional trellis decoder, such as the Viterbi decoder known in the art, which is set for decoding of the corresponding constituent RSC code. In another preferred embodiment, the RSC code is decoded sub-optimally using sequential decoding.

The iterative decoding loop begins at Soft-decision Decoder SD0 40. The inputs to SD0 40 are two sequences: the a priori metric sequence, M_{Y}⁰, and the soft-input metric sequence,

$${φ}_{i}^{0} .$$

In the trellis embodiment, the trellis decoder branch metrics are computed from M_{Y}⁰ and

$${φ}_{i}^{0} .$$

The output of SD0 40 for iteration i is a soft-decision estimate of the data sequence,

$${\hat{X}}_{i}^{0} ,$$

corresponding to the information sequence along the surviving path.

Soft-input Calculator SI1 42 continues the iterative decoding loop. SI1 42 calculates a soft-input metric sequence,

$${φ}_{i}^{1} ,$$

for Soft-decision Decoder SD1 44. This sequence is calculated by a function of the form:

$${φ}_{i , k}^{1} = {f}^{′} ( i , {M}_{{x}_{k}} , {\hat{X}}_{i , k}^{0} , {φ}_{i , k}^{0} ) ,$$

where

$${φ}_{i}^{1}$$

is a function of the a priori metric M_{X}, the soft-input metric sequence

$${φ}_{i}^{0} ,$$

and the soft-decision

$${\hat{X}}_{i}^{0}$$

of decoder SD0 40. Sequence

$${φ}_{i}^{1}$$

may also depend on the iteration number, i. In the preferred embodiment, Soft-input Calculator SI1 42 comprises an interleaver, to interleave data sequences in order to compensate for the coordinate shuffling created by the interleaving in the encoder. Preferred embodiments of this function are discussed later in this document.

Soft-decision Decoder SD1 44 then decodes its input sequences, M_{Y}¹ and

$${φ}_{i}^{1} ,$$

to obtain a soft-decision decoded sequence,

$${\hat{X}}_{i}^{1} .$$

In the trellis embodiment, the trellis decoder structure may differ from that of SD0 40, in accordance with the encoder coding strategy . The branch metrics are computed from the input sequences, M_{Y}¹ and

$${φ}_{i}^{1} ,$$

where the values in the soft-input metric sequence φₜ¹ are those calculated previously by Soft-input Calculator SI1 42. The output of SD1 44 for iteration i is a second soft-decision estimate of the data sequence, \hat{X}ₜ¹, corresponding to the information sequence along the surviving path of the trellis detector.

Analyzer 48 monitors the number of iterations which have been performed, and the data sequence estimates as they are generated by the Soft-decision Decoders. As each soft-decision estimate of the data sequence is generated, Analyzer 48 uses the monitored inputs to determine when the decoding process should be terminated by using a termination condition. Several preferred embodiments of termination conditions are described below. When the Analyzer 48 determines that the termination condition is met, the decoding process terminates, and a hard-output decoded sequence, \hat{X}, is selected as the decoder output.

If the Analyzer 48 determines that the termination condition has not been satisfied, the decoding process continues. In this case, the Iteration Counter 38 increments the iteration count, i, by one. Next, Soft-input Calculator SI0 46 calculates new values for soft-input metric sequence,

$${φ}_{i}^{0} ,$$

for use by Soft-decision Decoder SD0 40 during the next iterative decoding loop. The new values are calculated by a function analogous to the function used by SI1 42. The function is of the form:

$${φ}_{i , k}^{0} = f ( i , {M}_{{x}_{k}} , {\hat{X}}_{i - 1 , k}^{1} , {φ}_{i - 1 , k}^{1} ) ,$$

As seen from the above,

$${φ}_{i}^{0} ,$$

is a function of the a priori metric Mₓ, the soft-input metric sequence

$${φ}_{i - 1}^{1}$$

of decoder SI1 42, and the soft-decision sequence

$${\hat{X}}_{i - 1}^{1}$$

of decoder SD1 44, as obtained in the previous iteration. The function f( . . . ) may also depend on the iteration number i. In general, the function f( . . . ) is not necessarily the same as the function f′( . . . ) given above. In the preferred embodiment, Soft-input Calculator SI0 46 comprises an interleaver, which performs the same function as the interleaver in Soft-input Calculator SI1 42.

There are several preferred embodiments for Analyzer 48. These embodiments differ primarily in the termination conditions used by the Analyzer 48 to determine when to terminate the iterative decoding process.

In a first preferred embodiment, the iterative process is terminated when a desired reliability level has been reached. In one preferred embodiment of this type, the decoding process is terminated if the decoded hard-output sequence is a codeword of a pre-coded CRC code. In a second embodiment of this type, the decoding process is terminated if the Euclidean distance between the received sequence and the decoded hard-output sequence falls within a predetermined range.

In another preferred embodiment of Analyzer 48, the iterative process is terminated when additional iterations only marginally improve decoder performance. In one preferred embodiment of this type, the decoding process is terminated when sequence

$${\hat{X}}_{i}^{1}$$

at the output of SD1 44 and sequence

$${\hat{X}}_{i}^{0}$$

at the output of SD0 40 differ in only a small number of positions. In another preferred embodiment of this type, the decoding process is terminated when two estimated sequences obtained from successive iterations, for example

$${\hat{X}}_{i - 1}^{1}$$

and

$${\hat{X}}_{i}^{1} ,$$

differ in only a small number of positions.

In an additional preferred embodiment, the conditions for iterative decoding loop termination are based upon decoding complexity and allocated processing power considerations. For example, the loop is terminated when a predetermined number of iterations have been performed.

Other preferred embodiments of Analyzer 48 are based upon combinations of the conditions described above. For example, reliability and complexity conditions may be combined, and the decoding process terminated once a maximum number of decoding iterations are performed, even if the defined reliability condition is not satisfied.

There are also several preferred embodiments for functions f( . . . ) and f′( . . . ) used by Soft-input Calculators SI0 46 and SI1 42. A first preferred embodiment of these functions defines them as follows. First, a difference function Δ is defined as:

$${Δ}_{i , k}^{j} ≡ \vert HD ( {φ}_{l , k}^{j} ) - {\hat{X}}_{i , k}^{j} \vert ,$$

where HD

$$( {φ}_{i , k}^{j} )$$

denotes a hard-decision of the k-th information bit, wherein a hard-decision is made by deciding the binary value of the information bit based on its soft-decision value. In accordance with this definition, Δ equals 0 when

$$HD ( {φ}_{i , k}^{j} ) = {\hat{X}}_{i , k}^{j} .$$

Otherwise, Δ equals 1, thereby indicating whether the hard-decision and the decoded output sequence are in agreement. The function f′( . . . ), used by SI0 46, may then be given by:

$${φ}_{i , k}^{1} = ( 1 - {Δ}_{i , k}^{0} ) ( {φ}_{i , k}^{0} - {( - 1 )}^{{\hat{X}}_{i , k}^{0}} \cdot {c}_{0} ) - {Δ}_{i , k}^{0} ( {φ}_{i , k}^{0} - {( - 1 )}^{{\hat{X}}_{i , k}^{0}} \cdot {d}_{0} ) , \qquad ( \text{2.a} )$$

where c₀ and d₀ are two real-number coefficients. Similarly, the function f( . . . ) used by SI1 42, is given by:

$${φ}_{i , k}^{0} = ( 1 - {Δ}_{i , k}^{1} ) ( {φ}_{i , k}^{1} - {( - 1 )}^{{\hat{X}}_{i , k}^{1}} \cdot {c}_{1} ) - {Δ}_{i , k}^{1} ( {φ}_{i , k}^{1} - {( - 1 )}^{{\hat{X}}_{i , k}^{1}} \cdot {d}_{1} ) , \qquad ( \text{2.b} )$$

where c₁ and d₁ are real-number coefficients.

An alternative preferred embodiment of functions f( . . . ) and f′( . . . ) employs predefined soft-input values, h₀ and h₁. The soft-input metric sequences,

$${φ}_{i}^{0} and {φ}_{i}^{1} ,$$

are calculated from the corresponding decision obtained from a Soft-decision Decoder as follows:

$$\begin{matrix}{φ}_{i , k}^{1} = {( - 1 )}^{{\hat{X}}_{i , {k}^{ + 1}}^{0}} \cdot {h}_{0} & ( \text{3.a} ) \\ {φ}_{i + l , k}^{0} = {( - 1 )}^{{\hat{X}}_{i , {k}^{ + 1}}^{1}} \cdot {h}_{1} . & ( \text{3.b} )\end{matrix}$$

Other preferred embodiments of functions f( . . . ) and f′( . . . ) use a combination of the above definitions. In one preferred embodiment, f′( . . . ) is set equal to equation (3.a) and f( . . . ) is set equal to equation (2.b).

An embodiment of the present invention has been employed for decoding the turbo code defined in third generation (3G) wireless technology standards. Table 1 gives an example of a decoding strategy that was tested.

TABLE 1
Decoding Strategies

| Iteration Number | ƒ′ | ƒ |
|---|---|---|
| 1 | (2.a) | (2.b) |
| 2 | (3.a) | (3.b) |
| 3 | (3.a) | (2.b) |
| 4 | (2.a) | (2.b) |

Each row in Table 1 represents a different iteration. The first column indicates the iteration number. The second and third columns indicate the function chosen for f( . . . ) and f′( . . . ), where the numbers refer to the functions given above, using the following function parameter settings:

c₀=c₁=2.0

d₀=d₁=2.5

h₀=h₁=3.0.

Using the decoding strategy of Table 1, the present embodiment reduces the decoding complexity by a factor of 16 as compared to the state-of-the-art Max-Log-MAP decoder. At an output bit error rate of 10⁴, the penalty paid for this reduction in coding complexity is less than 1.5 dB.

The embodiments discussed above refer to a turbo code in which the encoded sequence transmitted over the channel comprises a data sequence, and two coded sequences derived from the data sequence. Higher-dimensional generalizations of the above embodiments may be constructed, to decode encoded sequences comprising more than three sub-sequences.

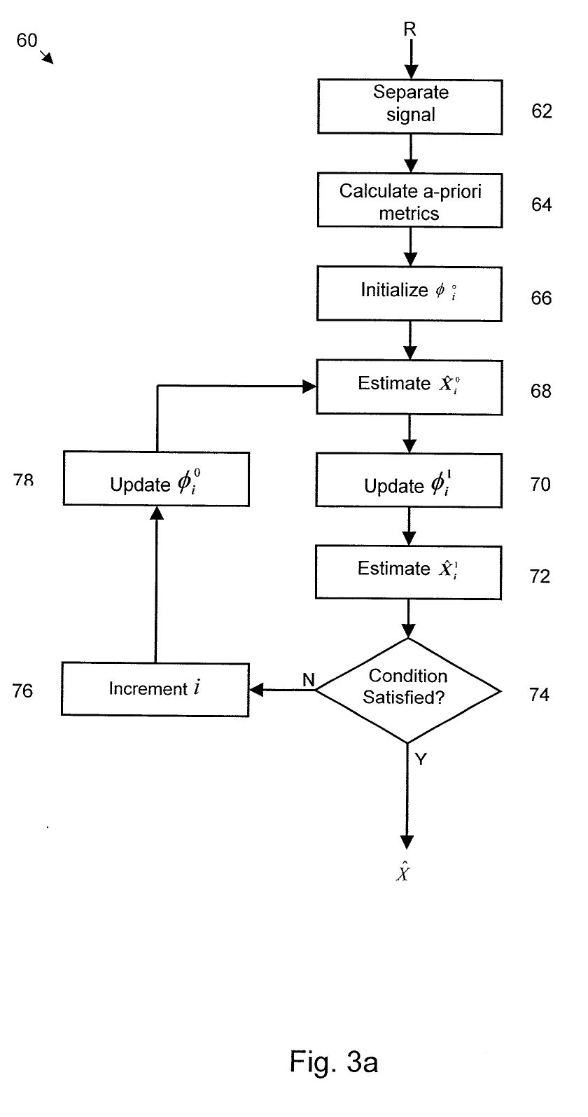

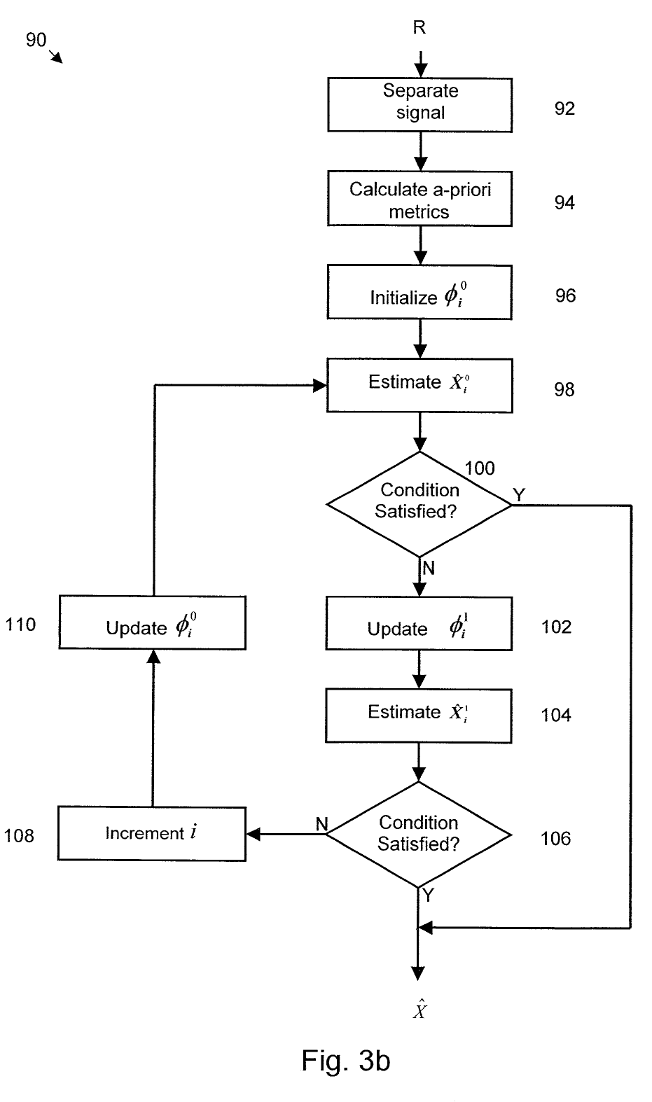

Reference is now made to FIG. 3a, which is a simplified flow chart of an embodiment of a method for decoding turbo codes. The input to the decoding process is the received signal R, where R=(x, y⁰, y¹) is a noisy version of the transmitted sequence C=(X, Y⁰, Y¹).

The received signal R is first separated into the three sub-sequences x, y⁰, and y¹, in step 62. In step 64, these sub-sequences are used to calculate the a priori metric sequences, M_{X}, M_{Y}⁰, and M_{Y}¹. These a priori metric sequences are stored for further use during the decoding process.

In step 66, the iteration count, i, and the soft-input metric sequence sequence,

$${φ}_{1}^{0} ,$$

are initialized as follows:

$$i = 1$$

$${φ}_{1}^{0} = {M}_{x} .$$

The sequence φ₁⁰ is required to calculate soft-decision decoded sequence

$${\hat{X}}_{i}^{0} .$$

The iteration count, i, is incremented each time the iterative decoding loop is entered.

Entering the iterative decoding loop in step 68, sequences M_{Y}⁰ and

$${φ}_{i}^{0}$$

are decoded to obtain a soft-decision decoded sequence,

$${\hat{X}}_{i}^{0} .$$

In the preferred embodiment, the decoding is performed by a trellis decoder, and the trellis decoder branch metrics are computed from these sequences.

Next, in step 70, the soft-input metric sequence,

$${φ}_{i}^{1} ,$$

is calculated by a function of the form:

$${φ}_{i , k}^{1} = {f}^{′} ( i , {M}_{{x}_{k}} , {\hat{X}}_{i , k}^{0} , {φ}_{i , k}^{0} ) ,$$

where ƒ′ is a function of the a priori metric M_{X}, the soft-input metric sequence

$${φ}_{i}^{0} ,$$

and the soft-decision decoded sequence

$${\hat{X}}_{i}^{0} .$$

The function ƒ′ may also depend on the iteration count, i. Step 70 may also comprise interleaving data sequences, in order to compensate for the coordinate shuffling created by the interleaving in the encoder.

In step 72, the sequences M_{Y}¹ and

$${φ}_{i}^{1}$$

are decoded to obtain a second soft-decision decoded sequence,

$${\hat{X}}_{i}^{1} .$$

As in step 68, in the preferred embodiment the decoding is performed by a trellis decoder. The trellis decoder branch metrics are computed from sequences M_{Y}¹ and

$${φ}_{i}^{1} ,$$

where the values of the soft-input metric sequence

$${φ}_{i}^{1}$$

are those calculated in step 70.

The iterative decoding loop terminates when a predetermined condition is satisfied, as shown in step 74. The termination condition is based on considerations such as reliability, convergence, and complexity restriction, as described above with respect to FIG. 2. If the termination condition is satisfied, the decoding process terminates, and a hard-output decoded sequence, \hat{X}, is provided as output.

If the termination condition is not satisfied, a new iterative decoding loop is entered. To prepare for the new iterative decoding loop, the iteration count, i, is first incremented in step 76. Next the soft-input metric sequence,

$${φ}_{i}^{0} ,$$

is recalculated in step 78 from a function analogous to the one used to calculate

$${φ}_{i}^{1} .$$

This function is of the form:

$${φ}_{i , k}^{0} = f ( i , {M}_{{x}_{k}} , {\hat{X}}_{i - 1 , k}^{1} , {φ}_{i - 1 , k}^{1} ) ,$$

where ƒ is a function of the a priori metric Mₓ, the soft-input metric sequence φₜ₋₁^{I}, and the decoded sequence \hat{X}ₜ₋₁¹, as obtained in the previous iteration, and where ƒ may also depend on the iteration number. The function f( . . . ) is not necessarily the same as the function f′( . . . ) given above. Finally, the iterative decoding loop is reentered at step 68. The decoding process continues until the termination condition is satisfied in step 74, and the hard-output decoded sequence, \hat{X}, is output.

Reference is now made to FIG. 3b, which is a simplified flow chart of an embodiment of a variation of the above described method for decoding turbo codes. The method illustrated in FIG. 3b differs from the method of FIG. 3a only by an additional test on the termination condition in step 100. In this method, the termination condition is tested after

$${\hat{X}}_{i}^{0}$$

is estimated in step 98, but before

$${\hat{X}}_{i}^{1}$$

is estimated in step 104. The method selected for a specific embodiment, that of FIG. 3a or of FIG. 3b, is determined by the requirements imposed by the choice of termination condition for that embodiment.

When deploying cellular wireless networks, systems are often designed to meet certain quality of service (QoS) requirements by employing sophisticated and computationally demanding error correction schemes. During the early stages of deployment there may be only a small number of users, and consequently lower levels of interference. Nevertheless, even with only a few customers in a system (i.e., lower interference levels), expensive, high-power consuming DSPs that support such complex error correction are still provided at the handsets without the customer revenue to support these expenses. Alternatively, standard DSPs may be used, resulting in lower peak data rates. The present embodiments can be employed to ease this problem, typically encountered in the early stages of network deployment, by allowing an increase in the data rate without sacrificing the QoS.

In later stages of network deployment, the present embodiments may be used for trading data rate with SINR when the conditions allow an increase in the SINR. For example, when the user is near the base station the power transmitted by the base station to that particular user is relatively low, and can be increased without significantly affecting other users in the cell or neighboring cells.

Although iterative decoding is significantly less complex than optimal decoding, it remains a computationally complex task. The present embodiments meet the need for a decoder that reduces overall processing requirements for decoding turbo codes. The present embodiments require only 18 cycles per bit for two iterations, leading to a reduction in complexity by a factor of 16 compared with 4 iterations of Max-Log-MAP decoding. The above dramatic decrease in computational complexity is particularly useful in cases where the conditions provide an increased SINR at the decoder input. The results obtained for 2-dimensional turbo codes are very close to the theoretical limits.

It is appreciated that certain features of the invention, which are, for clarity, described in the context of separate embodiments, may also be provided in combination in a single embodiment. Conversely, various features of the invention which are, for brevity, described in the context of a single embodiment, may also be provided separately or in any suitable subcombination.

It will be appreciated by persons skilled in the art that the present invention is not limited to what has been particularly shown and described hereinabove. Rather the scope of the present invention is defined by the appended claims and includes both combinations and subcombinations of the various features described hereinabove as well as variations and modifications thereof which would occur to persons skilled in the art upon reading the foregoing description.

We claim:

1. A decoder, for decoding a data sequence received from a noisy channel into an estimate of an input sequence, comprising a soft-decision decoder combined with a soft-input calculator, wherein said elements are interconnected, thereby to jointly converge on said estimate.

2. A decoder according to claim 1, wherein said data sequence is a turbo code comprising at least two interleaved sub-sequences, the soft-decision decoder comprising at least two soft-decision sub-decoders, and the soft-input calculator comprising at least two soft-input sub-calculators, each soft-decision sub-decoder respectively combined with a soft-input sub-calculator, for decoding respective sub-sequences.

3. A decoder according to claim 2, additionally comprising a separator operable to separate said turbo code into said sub-sequences.

4. A decoder according to claim 3, additionally comprising a metric calculator operable to calculate sets of a-priori metrics for each of said sub-sequences.

5. A decoder according to claim 4, wherein said a-priori metrics for at least one of said sub-sequences are Likelihood metrics.

6. A decoder according to claim 4, additionally comprising an initializer operable to initialize a set of soft-input metrics for at least one of said sub-sequences.

7. A decoder according to claim 4, additionally comprising an analyzer operable to analyze a current decoding state of said decoder, to determine whether a predetermined condition is met, and if so to terminate said decoding process and to output a hard-output decoded estimate of said input sequence.

8. A decoder according to claim 2, wherein said soft-decision sub-decoder comprises a trellis decoder.

9. A decoder according to claim 4, additionally comprising an iteration counter operable to count a number of decoding iterations performed by said decoder.

10. An iterative turbo code decoder for decoding a turbo-encoded data sequence received from a noisy channel, comprising:
a separator operable to separate the received data sequence into a first, a second, and a third component data sequence;
a metric calculator, having an input from said separator, operable to calculate a set of a-priori metrics for each of said component data sequences;
an initializer, having an input from said metric calculator, operable to initialize a first soft-input metric sequence;
a first soft-decision decoder, having inputs from said metric calculator and said initializer, operable to produce a first soft-decision decoded sequence;
a first soft-input calculator, having inputs from said metric calculator, said first soft-decision decoder, and said initializer, operable to calculate and subsequently update the values of a second soft-input metric sequence;
a second soft-decision decoder, having inputs from said metric calculator and said first soft-input calculator, operable to produce a second soft-decision decoded sequence;
a second soft-input calculator, having inputs from said metric calculator, said first soft-input calculator, and said second soft-decision decoder, and outputs to said first soft-decision decoder and said first soft-input calculator, operable to calculate and subsequently update the values of said first soft-input metric sequence; and,
an analyzer, having inputs from said first and said second soft-decision decoders, operable to analyze a current decoding state of said decoder, to terminate said decoding process if a predetermined condition is met, and to output a hard-output decoded estimate of said first sequence.

11. An iterative turbo code decoder for decoding a data sequence received from a noisy channel according to claim 10, wherein said at least one of said soft-decision decoders comprises a trellis decoder.

12. An iterative turbo code decoder for decoding a data sequence received from a noisy channel according to claim 10, wherein said first and said second soft-input calculators are connected in a loop, such that an output of said first soft-input calculator is connected to an input of said second soft-input calculator, and an output of said second soft-input calculator is connected to an input of said first soft-input calculator.

13. An iterative turbo code decoder for decoding a data sequence received from a noisy channel according to claim 10, wherein at least one of said soft-input calculators comprises an interleaver for interleaving data sequences.

14. An iterative turbo code decoder for decoding a data sequence received from a noisy channel according to claim 10, wherein said separator comprises a puncturer.

15. An iterative turbo code decoder for decoding a data sequence received from a noisy channel according to claim 10, wherein said analyzer is operable to terminate said decoding process when a predetermined reliability condition is fulfilled.

16. An iterative turbo code decoder for decoding a data sequence received from a noisy channel according to claim 10, wherein said analyzer is operable to terminate said decoding process when a decoded sequence produced by said turbo code decoder is a codeword of a predetermined encoding scheme.

17. An iterative turbo code decoder for decoding a data sequence received from a noisy channel according to claim 10, wherein said analyzer comprises a Euclidean distance measurer operable to terminate said decoding process when a Euclidean distance between a component data sequence and a decoded sequence produced by said turbo code decoder falls within a predetermined range.

18. An iterative turbo code decoder for decoding a data sequence received from a noisy channel according to claim 10, wherein said analyzer is operable to terminate said decoding process when two decoded sequences estimating said first component data sequence fulfill a convergence condition.

19. An iterative turbo code decoder for decoding a data sequence received from a noisy channel according to claim 10, wherein said analyzer comprises a Hamming distance measurer operable to terminate said decoding process when said first soft-decision decoded sequence and said second soft-decision decoded sequence differ from each other in no more than a predetermined number of positions.

20. An iterative turbo code decoder for decoding a data sequence received from a noisy channel according to claim 10, wherein said analyzer comprises a Hamming distance measurer operable to terminate said decoding process when soft-decision decoded sequences obtained after at least two successive decoding iterations differ in no more than a predetermined number of positions.

21. An iterative turbo code decoder for decoding a data sequence received from a noisy channel according to claim 10, wherein said analyzer is operable to terminate said decoding process when the decoding process has reached a predetermined level of complexity.

22. An iterative turbo code decoder for decoding a data sequence received from a noisy channel according to claim 10, wherein said analyzer comprises a counter operable to terminate said decoding process after a predetermined number of decoding iterations.

23. An iterative turbo code decoder for decoding a data sequence received from a noisy channel according to claim 10, wherein said a-priori metrics for at least one of said component data sequences are Likelihood metrics.

24. An iterative turbo code decoder for decoding a data sequence received from a noisy channel according to claim 10, wherein said initializer is operable to initialize a set of soft-input metrics by setting said set of soft-input metrics equal to the a-priori metrics of said first data sequence.

25. An iterative turbo code decoder for decoding a data sequence received from a noisy channel according to claim 10, additionally comprising an iteration counter operable to maintain an iteration count of a number of decoding iterations performed by said decoder.

26. An iterative turbo code decoder for decoding a data sequence received from a noisy channel according to claim 25, wherein said first soft-input calculator is operable to calculate the values of said second soft-input metric sequence additionally based on said iteration count.

27. An iterative turbo code decoder for decoding a data sequence received from a noisy channel according to claim 25, wherein said second soft-input calculator is operable to calculate the values of said first soft-input metric sequence additionally based on said iteration count.

28. An iterative method for decoding a data sequence encoded using turbo coding from a data sequence received from a noisy channel, comprising:
separating the received data sequence into a first, a second, and a third component data sequence;
calculating a set of a-priori metrics for each of said component data sequences;
initializing at least one of a first set and a second set of soft-input metrics;
performing an estimation cycle to decode said first component sequence, by:
producing a first soft-decision decoded sequence from said first set of soft-input metrics and from the set of a-priori metrics for said second sequence;
calculating the values of said second set of soft-input metrics from said first soft-decision sequence, from said set of a-priori metrics for said first sequence, and from said first set of soft-input metrics;
producing a second soft-decision decoded sequence from said second set of soft-input metrics and from the set of a-priori metrics for said third sequence;
determining if a predetermined condition for terminating said decoding process is met;
if said predetermined condition is met, discontinuing said decoding process by outputting a hard-output decoded sequence estimating said first sequence; and,
if said predetermined condition is not met, continuing the decoding process by:
updating said first set of soft-input metrics from said second soft-decision decoded sequence, from said set of a-priori metrics for said first sequence, and from said second set of soft-input metrics; and,
repeating said estimation cycle to update said first and second soft-decision decoded sequences and said first and second soft-input metrics until said predetermined condition is met.

29. An iterative method for decoding a data sequence encoded using turbo coding according to claim 28, wherein said method comprises interleaving within the decoding loop to ensure alignment of the decoded sequences within the loop.

30. An iterative method for decoding a data sequence encoded using turbo coding according to claim 28, wherein initializing a set of soft-input metrics comprises:
setting said set of soft-input metrics equal to the a-priori metrics of said first data sequence.

31. An iterative method for decoding a data sequence encoded using turbo coding according to claim 28, wherein producing a soft-decision decoded sequence is performed by trellis decoding.

32. An iterative method for decoding a data sequence encoded using turbo coding according to claim 28, wherein separating the received data sequence into component data sequences is performed by puncturing said received sequence.

33. An iterative method for decoding a data sequence encoded using turbo coding according to claim 28, wherein determining if a predetermined condition for terminating said decoding process is me t comprises determining whether at least one of said decoded sequences fulfills a predetermined reliability condition.

34. An iterative method for decoding a data sequence encoded using turbo coding according to claim 33, wherein said predetermined reliability condition includes a decoded sequence comprising at least one codeword of a predetermined encoding scheme.

35. An iterative method for decoding a data sequence encoded using turbo coding according to claim 33, wherein said predetermined reliability condition includes a Euclidean distance between a component data sequence and a decoded sequence falling within a predetermined range.

36. An iterative method for decoding a data sequence encoded using turbo coding according to claim 28, wherein determining if a predetermined condition for terminating said decoding process is met comprises determining whether two decoded sequences fulfill a convergence condition.

37. An iterative method for decoding a data sequence encoded using turbo coding according to claim 36, wherein s aid convergence condition comprises said first soft-decision decoded sequence and said second soft-decision decoded sequence differing in no more than a predetermined number of positions.

38. An iterative method for decoding a data sequence encoded using turbo coding according to claim 36, wherein said convergence condition includes a soft-decision decoded sequence yielded by at least two estimation cycles differing in no more than a predetermined number of positions.

39. An iterative method for decoding a data sequence encoded using turbo coding according to claim 28, wherein said predetermined condition for terminating said decoding process is a predetermined level of complexity of the decoding process.

40. An iterative method for decoding a data sequence encoded using turbo coding according to claim 36, wherein said predetermined level of complexity of the decoding process comprises having reached a predetermined number of decoding iterations.

41. An iterative method for decoding a data sequence encoded using turbo coding according to claim 28, wherein said a-priori metrics for at least one of said component data sequences are Likelihood metrics.

42. An iterative method for decoding a data sequence encoded using turbo coding according to claim 28, wherein said method further comprises maintaining an iteration count of the number of estimation cycles performed during the decoding process.

43. An iterative method for decoding a data sequence encoded using turbo coding according to claim 28, wherein the values of said first set of soft-input metrics are further calculated from said iteration count.

44. An iterative method for decoding a data sequence encoded using turbo coding according to claim 28, wherein the values of said second set of soft-input metrics are further calculated from said iteration count.
